(19) United States
(12) Patent Application Publication
(10) Pub. No.: US 2012/0200342 A1
(43) Pub. Date: Aug. 9, 2012

(54) GATE CONTROLLED PN FIELD-EFFECT TRANSISTOR AND THE CONTROL METHOD THEREOF

(75) Inventors: Pengfei Wang, Shanghai (CN); Songgan Zang, Shanghai (CN); Qingqing Sun, Shanghai (CN); Wei Zhang, Shanghai (CN)

(73) Assignee: Fudan University, Shanghai (CN)

(21) Appl. No.: 13/501,826

(22) PCT Filed: May 19, 2011
(86) PCT No.: PCT/CN2011/000872

§ 371 Date: Apr. 13, 2012

(30) Foreign Application Priority Data
Jun. 24, 2010 (CN) 201010209299.3

(51) Int. Cl. G05F 3/02; H01L 29/04; H01L 29/78

(52) U.S. Cl. 327/537; 257/412; 257/66; 257/E29.255; 257/E29.003

(57) ABSTRACT

The present invention belongs to the technical field of semiconductor devices, and more specifically, relates to a gate-controlled PN field-effect transistor and the control method thereof The gate-controlled PN field-effect transistor disclosed by the present invention comprises a semiconductor substrate region, a drain region and a source region on the left and right sides of the substrate region, and gate regions on the upper and lower sides of the substrate region. The gate-controlled PN field-effect transistor works in the positive bias state of the source-drain PN junction and is conducted from the middle of the substrate region. The gate-controlled PN field-effect transistor provided by the present invention decreases the leakage current and increases the drive current at the same time, namely decreases the chip power consumption and improves the chip performances at the same time. The present invention further discloses a method for controlling the gate-controlled PN field-effect transistor, including cut-off and conduction operation.

### BACKGROUND OF THE INVENTION

1. Technical Field

The present invention belongs to the technical field of semiconductor devices, relates to a semiconductor field-effect transistor and the control method, and especially to a gate-controlled PN field-effect transistor and the control method thereof.

2. Description of the Related Art

With the continuous development of integrated circuits, the dimensions of metal oxide silicon field effect transistors (MOSFET) becomes smaller and smaller, and the transistor density on unit arrays becomes higher and higher. Today, the technology node of integrated circuit devices is about 50 nm and the leakage current between the source and the drain of MOSFET is increasing rapidly with the decrease of channel length. Especially when the channel length decreases to smaller than 30 nm, a new-type of device shall be used to obtain smaller leakage current, thus decreasing the chip power consumption.

Gate-controlled PNPN field-effect transistors are transistors with extremely low leakage current capable of decreasing the chip power consumption significantly. The basic structure 100 of a gate-controlled PNPN field-effect transistor is as shown in FIG. 1, comprising a source region 102, a depletion region 103, a doped region 104 and a drain region 105 formed on the semiconductor substrate 101, and a gate region 108 formed by a gate 107 and a gate oxide layer 106. The doping types of the source region 102 and the drain region 105 are opposite. The region 102 having a doping type opposite to the source region 101 is a complete depletion region used to increase the transverse conductive region. The doping types of the doping region 103 and the source region 101 are the same. A P-N-P-N junction capable of decreasing the leakage current in the transistor is formed between the source region 102, depletion region 103, doping region 104 and drain region 105.

The leakage current of the gate-controlled PNPN field-effect transistor is lower than that of traditional MOS transistors and can decrease the chip power consumption significantly. However, as the dimensions of gate-controlled PNPN field-effect transistors decreases to less than 20 nm, its leakage current increases with the decrease of devices. The drive current of ordinary gate-controlled PNPN-effect transistors is 2-3 orders of magnitude lower than that of MOS transistors, so its drive current shall be increased so as to improve the performance of integrated gate-controlled PNPN field-effect transistor chips.

### BRIEF SUMMARY OF THE INVENTION

Therefore, the present invention aims at providing a new-type of semiconductor device structure capable of increasing the drive current of the transistor as well as restraining the increase of leakage current.

To achieve the purpose above of the present invention, a gate-controlled PN field-effect transistor is provided by the present invention, comprising:

A semiconductor substrate region;

A source region and a drain region on the left and right sides of the semiconductor substrate region;

Gate dielectric layers on the upper and lower sides of the semiconductor substrate region;

A gate covering the gate dielectric region.

Furthermore, the semiconductor substrate is made of single-crystalline or polycrystalline silicon with a thickness no more than 20 nm. The gate dielectric layers are made of one of SiO₂, Si₃N₄ and high k materials or the combination of some of them. The gate is made of one or more metal gate materials such as TiN, TaN, RuO₂, Ru, WSi or the doped polycrystalline materials or some of them.

The gate-controlled PN field-effect transistor provided by the present invention works in the positive bias state of the source-drain PN junction and is conducted from the middle of the substrate region. The gate-controlled PN field-effect transistor provided by the present invention can decrease the leakage current and increase the drive current at the same time, namely decrease chip power consumption and improve the chip performances at the same time, which is very applicable to the manufacturing of integrated circuit chips, especially low-power consumption chips.

A method for controlling the gate-controlled PN field-effect transistor above is also provided by the present invention, including conduction and cut-off operation.

The cut-off operation of the gate-controlled PN field-effect transistor is as follows:

Apply a first voltage to the gate;

Apply a second voltage to the drain;

The ranges of the first and second voltages are 0V to 3V and 0V to 0.7V respectively. Therefore, the PN junction between the source region and drain region of the gate-controlled PN field-effect transistor is biased positively and the gate voltage controls the substrate region to be depleted to form a depletion region, thus making the gate-controlled PN field-effect transistor in cut-off state.

The conduction operation of the gate-controlled PN field-effect transistor is as follows:

Apply a third voltage to the gate;

Apply a forth voltage to the drain;

The ranges of the third and forth voltages are −3V to 0V and 0V to 0.7V respectively.

Therefore, the PN junction between the source region and drain region of the gate-controlled PN field-effect transistor is biased positively, the width of the depletion region controlled by the gate voltage is narrowed, the gate-controlled PN field-effect transistor is in a conducting state and the current flows from the drain through the middle of the substrate region to the source.

The gate-controlled PN field-effect transistor provided by the present invention decreases the leakage current and increases the drive current at the same time, namely decreases the chip power consumption and improves the chip performances at the same time.

### BRIEF DESCRIPTION OF THE SEVERAL VIEWS OF THE DRAWINGS

FIG. 1 is the sectional view of a gate-controlled PNPN field-effect transistor in the prior art.

FIG. 2 is the sectional view of an embodiment of the gate-controlled PN field-effect transistor disclosed by the present invention.

FIG. 3a is the structural diagram when the gate-controlled PN field-effect transistor shown in FIG. 2 is cut off.

FIG. 3b is the band diagram of the structure shown in FIG. 3a.

FIG. 4a is the structural diagram when the gate-controlled PN field-effect transistor shown in FIG. 2 is conducted.

FIG. 4b is the band diagram of the structure shown in FIG. 4a.

FIG. 5 is the sectional view of another embodiment of the gate-controlled PN field-effect transistor disclosed by the present invention.

### DETAILED DESCRIPTION OF THE INVENTION

Exemplary embodiments of the present invention are further detailed hereinafter by referring to the drawings. In the drawings, for the convenience of description, the thickness of the layers and regions is magnified and the dimensions shown do not represents the actual ones. Although these drawings do not represent the actual device dimensions accurately, they show the relative positions of the regions and structures completely, especially the vertical and horizontal relations.

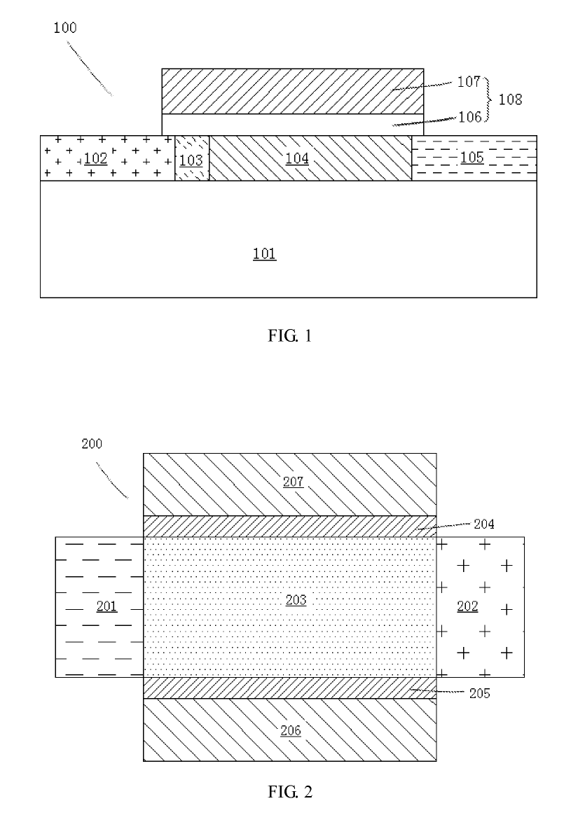

FIG. 2 shows an embodiment of a gate-controlled PN field-effect transistor structure 200 disclosed by the present invention, comprising an n-type source region 201, a p-type drain region 202, a semiconductor substrate region 203 between the n-type source region 201 and the p-type drain region 202, two gate dielectric layers 204 and 205 on the upper and lower sides of the semiconductor substrate region 203, and two metal gates 206 and 207. The doping concentration of the p-type drain region 202 and n-type source region 201 is preferably 2e19 cm⁻³, the semiconductor substrate region 203 can be a lightly doped n-type or p-type single-crystalline or polycrystalline silicon with a preferred doping concentration of 1e16 cm⁻³ and thickness of 20 nm.

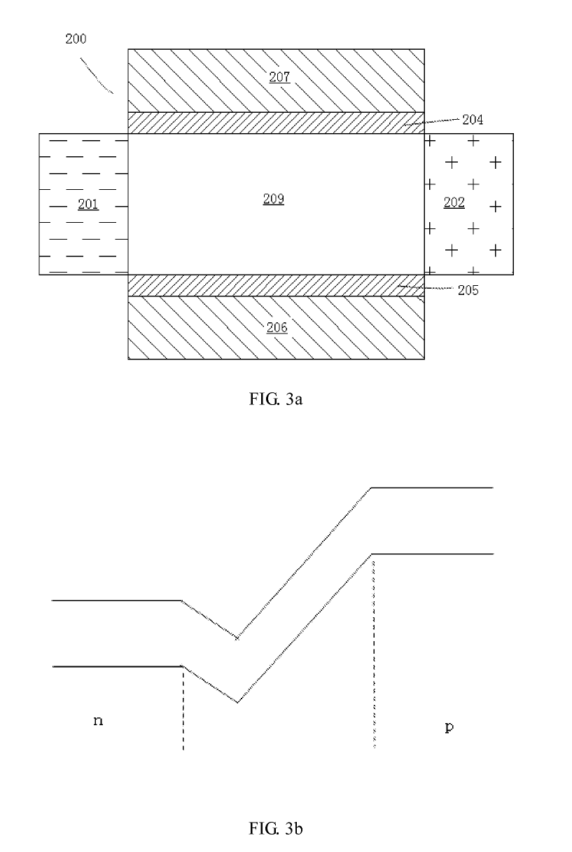

When cutting off the gate-controlled PN field-effect transistor structure 200 shown in FIG. 2, first, apply a positive voltage such as 0.2V, to the p-type drain region 202 so as to bias the PN junction between the p-type drain region and the n-type source region 201 positively. At the same time, apply a voltage, such as 0 V, to the metal gates 207 and 206 to deplete the semiconductor substrate region 203 to form a depletion region 209, thus making no current flow through the PN junction between the source region and drain region to make it in cut-off state, as shown in FIG. 3a, and the band diagram of the gate-controlled PN field-effect transistor structure 200 is as shown in FIG. 3b.

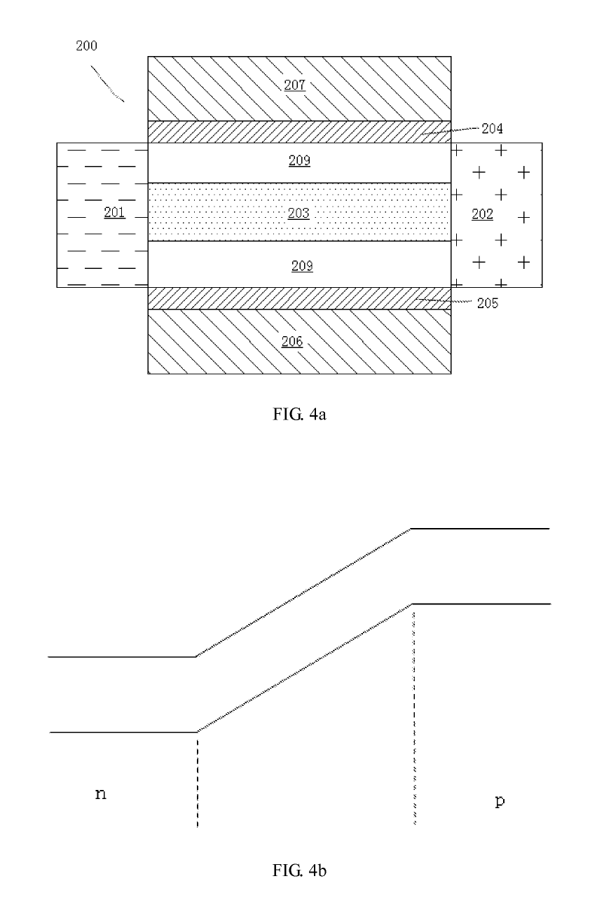

When conducting the gate-controlled PN field-effect transistor structure 200 shown in FIG. 2, first, apply a positive voltage, such as 0.2V, to the p-type drain region 202 so as to bias the PN junction between the p-type drain region and the n-type source region 201 positively. At the same time, apply a voltage, such as −2V, to the metal gates 207 and 206 to narrow the width of the depletion region 209 formed before. The PN junction between the source region and the drain region in positive bias state is conducted from the middle of the semiconductor substrate region, and the current flows from p-type drain region 202 to the n-type source region 201, as shown in 4a, and the band diagram of the gate-controlled PN field-effect transistor structure 200 is as shown in FIG. 4b.

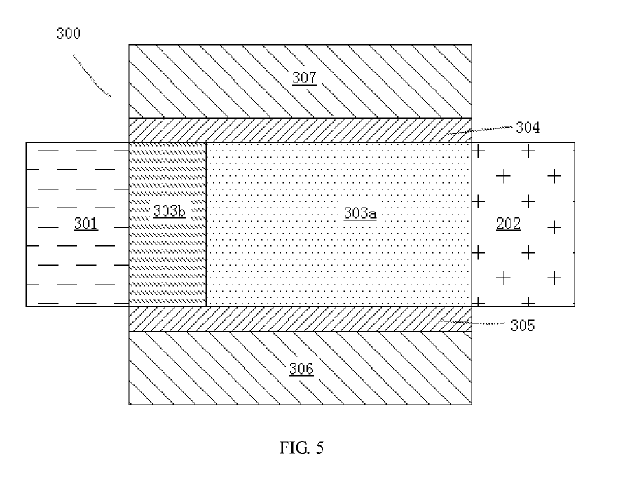

FIG. 5 is the sectional view of another embodiment of the gate-controlled PN field-effect transistor structure disclosed by the present invention. The gate-controlled PN field-effect transistor structure 300 comprises an n-type source region 301, a p-type drain region 302, two gate dielectric layers 304 and 305, and two metal gates 306 and 307. What is different from the gate-controlled PN field-effect transistor structure 200 shown in FIG. 2 is that, the semiconductor substrate region of the gate-controlled PN field-effect transistor structure 300 comprises a lightly doped p-type substrate region 303a and an n-type slowly changing region 303b capable of decreasing the leakage current of the transistor near the source 301 side.

As described above, there are many significantly different embodiments without deviating from the spirit and scope of the present invention. It shall be understood that the present invention is not limited to the specific embodiments described in the Specification except those limited by the Claims herein.

1. A gate-controlled PN field-effect transistor comprising:
a semiconductor substrate region;
a source region and a drain region on the left and right sides of the semiconductor substrate region;
gate dielectric layers on the upper and lower sides of the semiconductor substrate region;
a gate covering the gate dielectric region.

2. The gate-controlled PN field-effect transistor of claim 1, wherein the semiconductor substrate is made of single-crystalline or polycrystalline silicon.

3. The gate-controlled PN field-effect transistor of claim 1, wherein the semiconductor substrate is with a thickness no more than 20 nm.

4. The gate-controlled PN field-effect transistor of claim 1, wherein the gate dielectric layers are one of SiO₂, Si₃N₄ and high k materials or the combination of some of them.

5. The gate-controlled PN field-effect transistor of claim 1, wherein the gate is made of gate materials such as TiN, TaN, RuO₂, Ru, WSi or the doped polycrystalline materials or some of them.

6. A method for controlling the gate-controlled PN field-effect transistor as claim 1 including conduction and cut-off operation, the cut-off operation of the gate-controlled PN field-effect transistor is as follows:
apply a first voltage to the gate;
apply a second voltage to the drain;
therefore, the PN junction between the source region and drain region of the gate-controlled PN field-effect transistor is biased positively and the gate voltage controls the substrate region to be depleted to form a depletion region, thus making the gate-controlled PN field-effect transistor in cut-off state.
the conduction operation of the gate-controlled PN field-effect transistor is as follows:
apply a third voltage to the gate;
apply a forth voltage to the drain;
therefore, the PN junction between the source region and drain region of the gate-controlled PN field-effect transistor is biased positively, the width of the depletion region controlled by the gate voltage is narrowed, the gate-controlled PN field-effect transistor is in a conducting state and the current flows from the drain through the middle of the substrate region to the source.

7. The method for controlling the gate-controlled PN field-effect transistor as claim 6, wherein the ranges of the first and second voltages are 0V to 3V and 0V to 0.7V respectively.

8. The method for controlling the gate-controlled PN field-effect transistor as claim 6, wherein the ranges of the third and forth voltages are −3V to 0V and 0V to 0.7V respectively.
